(19) United States
(12) Patent Application Publication
(10) Pub. No.: US 2011/0149463 A1
(43) Pub. Date: Jun. 23, 2011

(54) ELECTRONIC DEVICE

(75) Inventors: Jonathan Redecen-Dibble, Northampton (GB); Stephen Boorer, Norfolk (GB)

(73) Assignee: ARORA GMBH, Luzern (CH)

(21) Appl. No.: 12/747,635

(22) PCT Filed: Dec. 15, 2008
(86) PCT No.: PCT/GB2008/004123

§ 371 Date: Mar. 7, 2011

(30) Foreign Application Priority Data
Dec. 13, 2007 (GB) 0724318.1
Jan. 3, 2008 (GB) 0800087.9

(51) Int. Cl. F23Q 3/00; H01L 23/14; H01L 23/29

(52) U.S. Cl. 361/263; 257/702; 257/790; 257/E23.005; 257/E23.119

(57) ABSTRACT

A rectifier comprising at least two wafers hermetically sealed within a first dielectric layer and connected to an input and an output, the rectifier further comprising a second dielectric layer overlying the first layer.

The present invention relates to an electronic device. More especially, the invention relates to an electronic device for an ignition system for a spark ignition internal combustion engine.

The operation of internal combustion engines is known to be fairly inefficient in terms of fuel combustion and wear of engine parts. The improvement of the operation of combustion engines in order to use fuel more efficiently is the subject of dedicated research across the world, especially in the present climate where evidence exists of increased, damage to the general environment through inefficient combustion techniques.

The ignition circuits of early motorised vehicles were based on a positive earth and, as such, worked under a negative polarity at the point electrode of the spark plug. It was, however, subsequently recognised that the negative polarity caused excessive corrosion of the components of the vehicle through oxidation. To overcome the problem of corrosion, later motorised vehicles used ignition circuits based on negative earth thereby working under positive polarity at the point electrode.

To this day, the ignition circuits of all spark ignition internal combustion engines are based on a positive earth arrangement. To change all the different components in modern vehicles required to convert modern vehicles to work under negative polarity would be highly problematic, to the extent of making it entirely impractical.

Many ignition circuits, particularly of CDI and improved systems, include a rectifier to convert positive alternating current into positive direct current. One end of the rectifier typically receives high voltage positive alternating current from the ignition coil. The rectifier converts the positive alternating current into a high voltage positive direct current which is outputted from the other end of the rectifier to a spark plug to initiate combustion. Following considerable and detailed testing, the Applicant has found that a negative direct current output at the point electrode for spark ignition reduces the amount of fuel required for ignition. Furthermore, the Applicant has found that a negative direct current output at the point electrode considerably reduces exhaust emissions.

Existing rectifiers generally comprise a plurality of silicon wafers linked together by junctions within a casing. The silicon wafers are typically passivated in glass, silica or polymer such that the silicon wafers are hermetically sealed within the casing.

The Applicant's earlier patent no. GB2330878 discloses an improved rectifier that is potted within a suitable dielectric compound to form a cylinder. The compound is used to avoid sparks being produced across the diode. Although performance of the resulting rectifier is greatly improved, it does not produce the effects of the present invention as are described hereinafter. The rectifier described in GB2330878 has a reverse recovery time of typically 200 ns. Furthermore the rectifier has been found to have a disparity between the forward and reverse voltage (32 kV compared to 24 kV).

The present invention relates to an improved rectifier which has a substantially lower recovery time, equal forward and reverse voltage and an overall enhanced performance when incorporated into an ignition circuit of a motorised vehicle. Moreover, the rectifier of the present invention has been found to generate a negative polarity on the point electrode of the spark plug and creates negative coronal phenomena.

According to one aspect of the invention there is provided a rectifier comprising at least two wafers hermetically sealed within a first dielectric layer and connected to an input and an output, each wafer having a length and width of less than 0.99 mm and having a junction therebetween of less than 0.040 inches, the rectifier further comprising a second dielectric layer overlying the first layer.

Preferably the wafers are silicon wafers.

Preferably the first layer surrounding the silicon wafers has a dielectric strength greater than 30 kV/mm.

Preferably still, a gap is provided between each junction and its neighbouring wafer.

Preferably the second layer has a dielectric strength of greater than 5 kV/mm.

The first and second layers are preferably constructed of materials of different dielectric strengths. Alternatively though they could be constructed of the same material.

According to a second aspect of the invention, there is provided an electronic component having at least two rectifiers constructed in accordance with the first aspect, connected in series.

One embodiment of the present invention will now be described, by way of example, with reference to the accompanying Figures, in which:

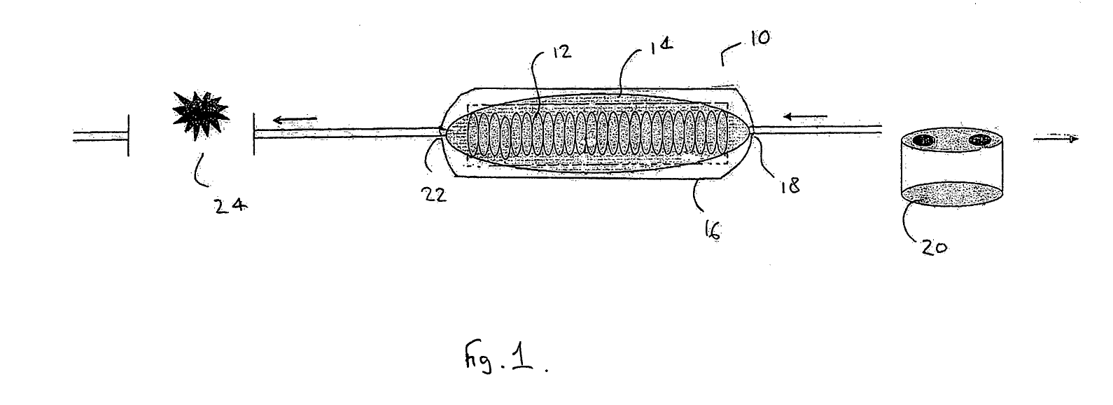

FIG. 1 is a schematic illustration of a rectifier constructed in accordance with the invention;

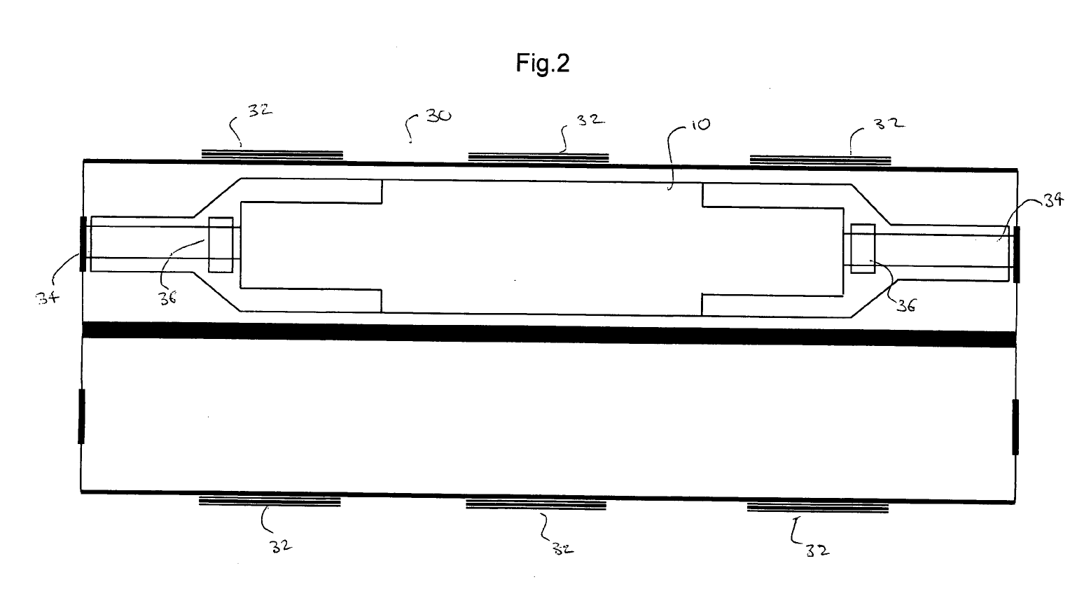

FIG. 2 is a schematic illustration of a rectifier casing in which the rectifier of FIG. 1 can be located; and

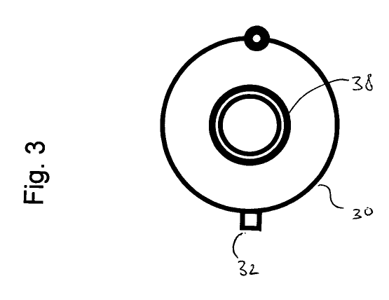

FIG. 3 is an end view of the rectifier casing of FIG. 2.

FIG. 1 illustrates schematically, a rectifier 10. The rectifier 10 comprises a plurality of silicon wafers 12 located within a first layer or casing 14. In a preferred embodiment, the rectifier 10 includes 24 silicon wafers but the number of wafers can vary considerably from but not limited to, for example, twenty to in excess of sixty.

The length and width of each wafer 12 is around 0.89 mm. This is significantly smaller than standard silicon wafers used in equivalent electronic components, which are typically 1 mm.

The wafers 12 are linked together by junctions (not clearly shown in the Figure). The junctions are square and have a diagonal length of 0.030 inches. The typical size of junctions of this kind would be around 0.040 inches. In other words, the junctions used in the present invention are substantially smaller than standard. A decrease in junction size has been found to increase the capacitance of the rectifier and to increase its speed of recovery, from 200 ns down to 20 ns in some tests conducted by the Applicant.

The rectifier 10 is specifically designed to enhance the reversed bias leakage via a precisely limited sputtering of the ultra-small silicon wafers 12 and the creation of an even smaller junction. Less dense doping of atoms of the toughs/ditches in the holes of the edges of the wafers 12 provide a leakage producing a direct negative N type negative charge in the majority over the P positive charge. The semiconductor metal doping is covered with a thermoplastic coating to protect the rectifier structure from damage. The metal used for the sputtering of the doping agent is 99.9% pure platinum.

P charges have an excess of positive charges and silicon wafer holes are minority carriers of the positive charge. N charges have an excess of negative charges via the dopant.

The dopant atoms create an N type charge, therefore smaller junctions will accumulate heat via the dopant to additionally create an excess of negative N charges from the above that of the P positive charge. So the reversed bias current through an N type charge is specifically designed into the present rectifier 10 and this is negative.

The rectifier 10 is designed with a specifically smaller gates or junctions to facilitate the reversed bias negative N charge created through an excess of N charge over the regular P positive charge.

All rectifiers have a leakage characteristic intrinsic to their structure. The present rectifier however has a specifically designed leakage creating a strong and reliable N type negative charge majority which is manifest at the point of electrical discharge over the electrode of the spark plug. This incorporates the powerful negative ion effect which consumes virtually all the air to fuel mixtures in the combustion engine.

The N type charge is discouraged through dense doping methods used to fill in the holes and troughs in the wafer and to seal the wafers together to create a strong P positive direct charge.

Thin film coating involves depositing precise layers of speciality materials in energised vacuum environments. These environments demand certified, high purity materials for repeatable results. By reducing the sputtering time of the high purity materials, in this case platinum, the deposits are reduced.

Under-doped insular states, which are coupled with a decreased partial pressure gas lowers the sputtering rate potential of the gas. Typically, therefore, a 10 minute sputtering of the doping material reduced to between 3 to 7 minutes reduces the sputtering depth accordingly. The reduced sputtering time will allow for a greater leakage to occur via the wafer holes and from the sides of the rectifier. This in a consistent and reliable manner, creates a controlled negative N type direct charge.

“Ion milling” may be employed to obtain a consistent predetermined sputtering depth of the Platinum and this depth can then be converted into time. It is understood that an increase in the wafer temperature during this sputtering will result in a fasted annealing of the platinum to the surface. Conversely where there is knowledge of the sputtering etch rate an accurate calculation of the depth may be made.

The overall length of the casing 14 is around typically 8.89 mm. Platinum doping is applied to the spaces between the wafers 12. The platinum sputtering is around 0.03 μm. A very slight gap is provided between the platinum sputtering at the end of each junction and the neighbouring wafer 12.

The wafers 12 are glass passivated to hermetically seal them within the layer 14.

The rectifier 10 has a second layer of casing 16 surrounding the first layer 14. The second layer 16 entirely encapsulates the first layer 14. The absence of any air gap between the two layers eliminates the possibility of arcing between the two layers.

Experiments conducted by the Applicant to date have identified two preferable materials for the second layer 16. Details of these will now be provided by way of example only, with no intended limitation.

One example of a material found to have desired features is a thermoset plastic. The plastic has a typical flame retardancy of V-0, a dielectric strength of 28 kV/mm and a thermal conductivity of 0.6 W/mK. Suitable properties of the casing compound would be high dimensional stability, non-flammable and high mechanical properties.

A further example of a suitable material for the layer 16 would be a cold-pour epoxy resin. The epoxy typically has a flame retardancy of V-0, a dielectric strength of 10 kV/mm and a thermal conductivity of 0.45 W/mK.

One end of the rectifier 10 is connected via an input 18 to an ignition coil 20. During use, the ignition coil transmits a flow of high voltage positive alternating current to the input 18 of the rectifier 10.

The other end of the rectifier 10 has an output 22 to provide a spark discharge 24.

In a preferred embodiment, two rectifiers 10 are connected in series within the ignition system, between the secondary winding of the coil and the point of the spark. The sizes of the wafers and the junctions, produce a single rectifier of low voltage rating than standard allowing two rectifiers to be used in series, by enabling a leaner air to fuel mixture (AFR) to produce the same power as a richer normal Lambda 1 mixture.

We refer now to FIGS. 2 and 3, which illustrate schematically a casing 30 suitable for holding a rectifier or rectifiers 10 as described.

The casing 30 is specifically designed to provide a water-proof casing for or each rectifier 10 to enable the rectifiers 10 to be located within part of an ignition circuit which may ordinarily be exposed to the atmosphere. As such, the casing 30 would provide application of the rectifiers in open vehicles such as tractors.

The casing 30 comprises a cylinder hinged along its longitudinal axis. Locking means 32 are provided to lock the two cylinder halves shut to prevent unauthorised access to the rectifiers 10 within the casing 30.

The rectifier within the casing 30 (shown as a simple block in FIG. 2) is connected at each end to an electric cable 34 via crimped metal clips 36 and outer cable hole gripping flanges 38 (see FIG. 3). The casing 30 is thus hermetically sealed to the leads of the ignition circuit.

The aforementioned description details construction of the rectifier 10. There follows a description of the effects of a rectifier 10 of such construction during its use as a component in the ignition circuit of a spark ignition engine.

Through considerable experimentation and testing, the Applicant has found that an electronic component with two of the rectifiers connected in series greatly enhances the performance of an engine to which it is installed. When connected in series, both rectifiers 10 are encapsulated within the second layer 16. In other words, reference to “rectifier” here relates to the silicon wafers hermetically sealed within a first layer.

It is understood that the rectifier 10, during use, creates an opportunity for a negative direct current output at the point electrode for spark ignition. This occurrence has been found to reduce the amount of fuel required for ignition. Furthermore, the occurrence has been found to considerably reduce exhaust emissions.

A negatively charged point electrode produces a spark with the characteristics relating to negative corona. The efficacy of negative corona over positive corona is well documented in scientific literature in various applications including the production of oxygen ion species, a key factor in combustion chemistry.

Furthermore, the specific construction of the rectifier 10 provides a recovery time of 20 ns, significantly less than known equivalent devices. Moreover, the specific construction of the rectifier 10 provides an equal forward and reverse voltage of 16 kV.

So multiples of the rectifier allow for increases of the input voltage and therefore 2 rectifiers would allow for an input voltage of 32 KV etc and etc. ie 10 would allow for an increased input voltage of up to 160 KV.

It is clear from all the experimental data that a rectifier constructed in accordance with the invention has dramatic advantages with respect to the efficiency of engines both in exhaust emissions and fuel savings.

It will be appreciated that the foregoing is merely an example of one embodiment and just one example of its use. The skilled reader will readily understand that modifications can be made thereto without departing from the true scope of the invention.

1. A rectifier comprising at least two wafers hermetically sealed within a first dielectric layer and connected to an input and an output, each wafer having a length and width of less than 0.99 mm and having a junction therebetween of less than 0.040 inches, the rectifier further comprising a second dielectric layer overlying the first layer.

2. A rectifier according to claim 1, wherein the wafers are silicon wafers.

3. A rectifier according to claim 1, wherein the first layer surrounding the silicon wafers has a dielectric strength greater than 30 kV/mm.

4. A rectifier according to claim 1, wherein a gap is provided between each junction and its neighbouring wafer.

5. A rectifier according to claim 1, wherein the second layer has a dielectric strength of greater than 5 kV/mm.

6. A rectifier according to claim 1, wherein the second layer is constructed from a thermoset plastic material.

7. A rectifier according to claim 1, wherein the second layer is constructed from a cold pour epoxy resin.

8. An ignition circuit for a vehicle having at least two rectifiers according to claim 1, connected in series between a secondary winding of a coil and the point of the spark within the ignition circuit.

9. A water-proof casing for one or more rectifiers according to claim 1, the casing comprising a cylinder hinged along its longitudinal axis and means to lock the two halves of the cylinder together.

10. A rectifier as hereinbefore described or referred to in the accompanying figures.
